(19) United States
(12) Patent Application Publication
(10) Pub. No.: US 2004/0038152 A1
(43) Pub. Date: Feb. 26, 2004

(54) Method for making printing plate by inkjet deposition on positive-working media

(76) Inventors: Jonathan W. Goodin, Tyler, TX (US); Brian J. Collister, Burnaby (CA)

Correspondence Address: MADSON & METCALF, GATEWAY TOWER WEST, SUITE 900, 15 WEST SOUTH TEMPLE, SALT LAKE CITY, UT, 84101

(21) Appl. No.: 10/617,151

(22) Filed: Jul. 10, 2003

Related U.S. Application Data
(60) Provisional application No. 60/395,641, filed on Jul. 15, 2002.

(51) Int. Cl. G03F 7/00

(52) U.S. Cl. 430/302

(57) ABSTRACT

An inkjet method is used to make a negative working offset lithographic printing master by imagewise application of liquid inkjet droplets that form a mask on a layer of positive-working radiation imageable material pre-coated on a hydrophilic lithographic base. The masked layer is then subjected to a developer and developed. After development, only the masked areas of the positive working imageable material remain. Since this material is hydrophobic the resulting imaged layer on the hydrophilic lithographic base may be employed as a wet offset lithographic master. Since the image that is printed by the printing master coincides directly with the image printed by the inkjetting process on the imageable material, the method is inherently negative-working. By the method of the present invention positive-working radiation imageable media is therefore employed to make a negative-working printing master. The combination of positive working radiation-imageable medium and masking fluid of this invention may be used in the fully on-press fabrication of a negative working lithographic master, which may optionally may also be made on a re-usable base.

### CROSS-REFERENCE TO RELATED APPLICATION

This application claims the benefit of Provisional Patent Application No. 60/395,641, filed Jul. 15, 2002.

### FIELD OF THE INVENTION

The invention pertains to the field of lithographic printing and, in particular, to the making of offset printing plates using inkjet technology

### BACKGROUND OF THE INVENTION

In the art of lithographic printing it is generally required that one or more lithographic printing plates (masters) be mounted on a printing press. In the case of wet offset lithographic printing, the lithographic printing (master) is characterized by having on its printing surface oleophilic-ink receiving areas in the form of the image to be printed, and hydrophilic water-receiving areas corresponding to the other, non-printing areas of the surface. Because of the immiscibility of oil-based lithographic inks and water, on a well-prepared printing master, ink will fully coat the oleophilic areas of the printing surface of the plate and not adhere to the hydrophilic areas. The operating press brings the inked master surface into intimate contact with an impression cylinder or elastic transfer blanket that transfers the ink image to the media to be printed.

Lithographic printing masters generally have images that are planographic, i.e., substantially flat. However, other printing plates with similar photosensitive coatings may have raised images for relief printing or intaglio images for gravure printing. Lithographic printing processes may use water as described above, or they may use a waterless printing technique. If a waterless technique is used, the discrimination between the inked and non-inked areas of the plate surface is based on having different surface energies in the imaged and unimaged areas, leading to differences in oleophilicity. Plates based on a silicone-formulation, being one of a very few practical materials that are inherently oleophobic, are typical examples.

Traditionally, a lithographic plate is photographically imaged. The plate substrate is most commonly aluminum, treated so that the printing surface is hydrophilic, although treated or untreated plastic or paper substrates are also used. The hydrophilic substrate is then coated with one or more layers of materials which function as the imageable layer of the plate. The deposited coatings vary considerably and much effort has been expended by many parties in the industry to develop coatings of increased sensitivity and durability. Coating layers are commonly about 1 to 3 microns in thickness.

At least one of the layers of the plate coating is sensitive to light of some wavelength or another. Ultra-violet, visible and infrared light-sensitive coating compositions for lithographic printing plates are well known in the art. Many conventional plates are ultraviolet-sensitive in the 325 nm to 400 nm range, being based on diazo materials, and lithographic printing plates suitable for offset printing are typically produced from these plates via processes similar to a photographic process.

To prepare a lithographic precursor for use as a wet offset printing plate, commonly referred to as a lithographic master, in order to differentiate between the blank plate (the precursor) and the processed plate, (the master) the plate is first exposed to light in the pattern to be printed using a photographic film negative. The exposed plate is then washed in a developing solution. In one group of plate products, known as negative-working plates, the exposed areas of the plate coating are insoluble and the development process quantitatively removes the unexposed areas of the coating from the hydrophilic aluminum surface of the plate substrate. By convention, such a preparation process is referred to as a negative-working process because the unexposed coating is removed. Diazonium salt-based plates, as a specific group, represent a typical example of conventional ultra-violet-sensitive negative-working plates.

Conversely, in a positive-working process, the pattern to be printed is masked and the photosensitive exposed coating is rendered soluble in a developer. Until after the development step, the printing artisan or press operator generally endeavors not to allow incidental exposure of the plate to typical white light or sunlight. Undeveloped plates are typically handled only in low light or “yellow light” rooms or conditions.

Traditionally, lithographic precursors have been imaged by photographic transfer from original artwork. Unfortunately, this process is labor-intensive and costly. Hence, with the advent of the computer engendering a revolution in the graphics design process preparatory to printing, there have been extensive efforts to directly pattern printing plates, in particular lithographic printing plates, using a computer-controlled apparatus such as a platesetter which is supplied with digital data corresponding to the image to be printed. A typical platesetter has the capability to supply an image-forming agent, typically light energy or one or more chemicals, to a precursor according to various images as defined by digital data, i.e., to imagewise apply an image-forming agent. The term “computer-to-plate” has been generally used to describe such machines that are capable of directly imaging printing precursors from computer data.

Typical computer-to-plate systems variously use ablative thermal plates, where the image is imparted to the plate by ablating away the areas that are not to be printed (inherently positive-working), and, more recently, thermal plates that are imaged with lower power laser beams that induce by various mechanisms a change in the hydrophilicity or oleophilicity of the imaged area. Typically, but not exclusively, comparatively lower cost near-infra-red diode lasers are employed and light-to-heat converter materials are added to the coating on the precursor to adapt the precursor to the wavelength of the laser. Both positive- and negative-working variants of such media have been developed.

A special type of a computer-to-plate process involves the exposure of a precursor while it is mounted on a plate cylinder of a printing press. This is done by means of an plate-setter that is integrated in the press. This method may be called “computer-to-press” and printing presses with an integrated plate-setter are sometimes called digital presses. A review of digital presses is given in the Proceedings of the Imaging Science & Technology's 1997 International Conference on Digital Printing Technologies (Non-Impact Printing 13). Computer-to-press (CTP) methods have been widely described and are well known to those schooled in the art of commercial printing. Typical plate materials used in computer-to-press methods are based on ablation. A problem associated with ablative plates is the generation of debris, which is difficult to remove and may disturb the printing process or may contaminate the exposure optics of the integrated image-setter. Other methods require wet processing with chemicals. Such processes may damage or contaminate the electronics and optics of the integrated image-setter and other devices of the press.

Whereas a precursor normally consists of a sheet-like support and one or more functional coatings, computer-to-press methods have been described wherein a composition, capable of forming a lithographic surface upon image-wise exposure and optional processing, is provided directly on the surface of a plate cylinder of the press. Techniques have also been described in which a coating of a hydrophobic layer is applied directly on the hydrophilic surface of a plate cylinder. After removal of the non-printing areas by ablation, a master is obtained. However, ablation should be avoided in computer-to-press methods, as discussed above. In U.S. Pat. No. 5,713,287 (Gelbart), a computer-to-press method is described wherein an imageable medium is applied directly on the surface of a plate cylinder. The imageable medium is converted from a first water-sensitive or oil-sensitive property to an opposite water-sensitive or oil-sensitive property by image-wise exposure.

Most of the computer-to-press methods referred to above use so-called thermal or heat-mode materials, i.e. precursors or on-press coatable compositions, which comprise a compound that converts absorbed light into heat. The heat which is generated on image-wise exposure triggers a (physico-)chemical process, such as ablation, polymerization, insolubilization by cross-linking of a polymer, decomposition, or particle coagulation of a thermoplastic polymer latex, and after optional processing, a lithographic image is obtained.

A computer-to-press method has also been disclosed in which an oleophilic substance is image-wise transferred from a foil to a rotary press cylinder by melting said substance locally with a laser beam. The strip-shaped transfer foil has a narrow width compared to the cylinder and is translated along a path which is parallel to the axis of the cylinder while being held in close contact with the surface of the cylinder so as to build up a complete image on that surface gradually. As a result, this system is rather slow and requires a long downtime of the printing press, thereby reducing its productivity.

An on-press coating method has been described wherein an aqueous liquid, comprising a hydrophilic binder, a compound capable of converting light to heat and hydrophobic thermoplastic polymer particles, is coated on the plate cylinder so as to form a uniform, continuous layer thereon. Upon image-wise exposure, areas of the coated layer are converted into a hydrophobic phase, thereby defining the printing areas of the printing master. Such methods of on-press coating, on-press exposure and on-press cleaning of the master are commercially attractive because, contrary to conventional lithographic printing, they can be carried out without specialized training or experience. Such presses require less human intervention than conventional presses.

Coating of plate masters off-press has existed since the 1960's as hand-wiped plates. This process, due to poor coating quality associated with hand coating, has fallen out of favour given increased demand for quality printing and has in general been replaced by pre-coated masters. In the case of hand-coated masters, however, the substrates were not reused. There is value in reusing the lithographic substrate as the materials and production of such substrate can be costly. This becomes even more feasible for shorter print runs where the mechanical properties of the substrate do not degrade significantly. There is thus interest in the process of reusing lithographic substrates by removing the lithographic master from the press, and installing it in a separate device whereby the printing surface is removed, the substrate is recoated, and optionally imaged for reuse in printing.

As may be seen from the foregoing, the technology of on-press imaging and on-site platemaking has made major strides and represents a major benefit to industry. However, a need remains associated with coating substrate materials, both on-press and in dedicated off-press coating and imaging equipment, in that operators of such facilities wish to have costs reduced as far as possible. This has led to the need for re-usable lithogrpahic masters. In the case of fully on-press platemaking, the lithographic support may be the cylinder of the press itself. As this is an expensive piece of high precision equipment, the platemaking process employed needs to allow for the repeated re-use of this cylinder.

Various attempts have been made to address this issue by creating cylinders that have permanent oxide or ceramic coatings that may be switched between various states of hydrophilicity by incident imagewise-applied radiation. The inherent problem with all of these switchable drum technologies is that inadequate lithographic latitude is obtained in that the variation in hydrophilicity induced in the permanent oxide or ceramic layer is simply inadequate to produce a reliable industrial result outside the laboratory under practical pressroom conditions.

Heretofore, many of the new CTP systems have been relatively large, complex, and expensive, being characterized by having sophisticated servo-mechanics and optics in order to both manage the light from laser arrays and provide the required resolution on the plate over large areas. They are often used by larger printing companies as a means to streamline the prepress process of their printing operations, and to take advantage of the rapid exchange and response to the digital information of graphic designs provided by their customers. There remains a strong need for a lower cost economical and efficient CTP system for the many smaller printers who utilize lithographic printing.

In recent years, inkjet printers have replaced laser printers as the most popular hard copy output printers for computers. Inkjet printers have several competitive advantages over laser printers. One advantage is that, as a result of semiconductor processing technological advances, it is possible to manufacture arrays of hundreds of inkjet nozzles spaced very accurately and closely together in a single inexpensive printhead. This nozzle array manufacturing capability enables fast printing inkjet devices to be manufactured at a much lower cost than laser printers requiring arrays of lasers. The precision with which such a nozzle array can be manufactured, combined with the jetting reliability of the incorporated nozzles, allow these arrays to be used to print high quality images comparable to photo or laser imaging techniques. Inkjet printers are increasingly being used for prepress proofing and other graphic arts applications requiring very high quality hard copy output. In spite of the large and rapidly-growing installed base of inkjet printers for hard copy output, inkjet printing technology is not commonly used in CTP systems.

There are many challenging technical requirements facing the practitioner who would design such an inkjet-based CTP system, as can be seen in the prior art. A first requirement is that the inkjet ink used to image the printing plate be jettable, able to form ink drops of repeatable volume and in an unvarying direction. Further, for practical commercial application, the ink must have a long shelf life, in excess of one year or more.

U.S. Pat. No. 5,970,873 (DeBoer et al.) describes the jetting of a mixture of a sol precursor in a liquid to a suitably-prepared printing substrate. However, any ink constituents of limited solubility will render unlikely the practical formulation of a jettable, shelf-stable ink. Similar problems exist in U.S. Pat. No. 5,820,932 (Hallman et al.), in which complex organic resins are jetted, and U.S. Pat. No. 5,738,013 (Kellet) in which marginally-stable transition metal complexes are jetted.

Another requirement is that, to be of wide utility, the inkjet-based CTP system must be able to prepare printing plates with small printing dots, approximately 75 microns in diameter or smaller, so that high resolution images can be printed. Inkjet printers can produce such small dots, but of those having substantial commercial acceptance, only inkjet printers employing aqueous-based inks and other low viscosity carriers or solvents are practically capable of printing such small dots. Thus, the systems described in U.S. Pat. No. 4,003,312 (Gunther), U.S. Pat. No. 5,495,803 (Gerber), U.S. Pat. No. 6,104,931 (Fromson et al.), and U.S. Pat. No. 6,019,045 (Kato), which use high viscosity hot melt inks, will not allow the preparation of the high resolution printing plates necessary for printed images of high quality.

It is also required that the prepared printing plates be rugged, capable of sustaining press runs of many thousands of impressions. The waxes used in the hot melt inks described in U.S. Pat. No. 6,019,045 (Kato) and U.S. Pat. No. 4,833,486 (Zerillo) would wear out in such a long press run.

Another requirement of a successful inkjet-based CTP system is that a mature plate technology is to be preferred. There are many tradeoffs in the manufacture of commercially-practical lithographic precursors. They must be highly sensitive to the imaging process and yet thermally stable, stable in high humidity storage environments and yellow light, resistant to fingerprints, of minimal toxicity and environmentally benign, easily developed in that small dots are quantitatively resolved without dot blooming using developers that are of minimal toxicity and environmentally benign, able to sustain long press runs, manufacturable at a low cost per square foot, and many other practical requirements.

U.S. Pat. No. 5,695,908 (Furukawa) describes a process for preparing a printing plate comprising a new plate coating containing a water-soluble polymer that becomes water-insoluble in contact with a metal ion in a solution jetted imagewise. But such a new plate coating is unlikely to meet the wide array of constraints on a successful plate technology. U.S. Pat. No. 6,025,022 (Matzinger) describes a new plate coating on a glass substrate that would be unlikely to find wide acceptance.

While there is a considerable body of art on the subject of platemaking via inkjet, those that address the making of non-relief lithographic ( that is, non-gravure and non-flexographic) plates very often focus on depositing the material that is to form oleophilic ink-bearing areas. Some processes are also specifically directed to the making of waterless plates in this way. In a more limited number of cases there is some form of chemical reaction, either between different inkjetted materials, or between inkjetted materials and materials pre-coated on the plate, to create, via this reaction, a third material composition which is either removed by development (positive-working) or which creates the areas to be inked (negative-working). Some inventions employ special additives to the ink or special chemicals on the plate surface to trigger, enhance or stimulate this process.

In U.S. Pat. No. 6,315,916 (Deutsch,et al.) describes an example of a reactive process for preparing wet offset lithographic plates by inkjet imaging of presensitized plates comprising “diazo” compounds. According to this process, an alkaline or chemically basic ink comprising one or more suitable pH-elevating chemicals is imagewise jetted onto a lithographic plate having a coating comprising “diazo” compounds. The latent image on the plate is cured by heating, and next developed by washing with a conventional chemical development solution.

### BRIEF SUMMARY OF THE INVENTION

The invention provides a method for making a negative-working lithographic master using a positive-working radiation-imageable medium on a hydrophilic base. The method comprises imagewise inkjet deposition of droplets of masking fluid on the surface of the positive-working radiation-imageable medium, forming a mask that is substantially resistant to a developer. The exposed areas of the medium, not covered by the mask, are then exposed to a developer capable of removing the exposed medium, such as a quaternary nitrogen compound in an aqueous carrier. As a result, those areas that are written with the masking fluid will, at the end of plate processing, be hydrophobic and will render an image during wet lithographic offset printing. Normally, when imaged with actinic radiation in the absence of a mask, the radiation-imageable lithographic medium is positive-working. By the method of the present invention, the same material, however, allows a negative-working lithographic master to be made. The combination of positive-working radiation-imageable medium and masking fluid of this invention may be used in the fully on-press fabrication of a negative-working lithographic master, which may optionally also be made on a re-usable base.

In an alternative embodiment of the invention, the masked medium is flood illuminated, for example with UV radiation, and the unmasked areas of the medium are then exposed to a developer capable removing such irradiated medium, for example an aqueous alkaline solution.

### DETAILED DESCRIPTION OF THE PREFERRED EMBODIMENTS

The method of the present invention comprises the use of a positive-working offset lithographic precursor, in the form of a hydrophilic lithographic base coated with positive-working radiation-imageable medium, to make a negative-working lithographic master. A latent image is created in the coating of the lithographic precursor by imagewise depositing of a chemical forming a mask that is substantially resistant to a developer, the mask being in the form of the image to be printed. This causes the masked area of the coating to be largely unaffected by the developer. The unmasked area of the coating is removable by the developer, without the need for irradiation with actinic radiation. It is simplest and preferred to formulate a masking fluid comprising the masking chemical, and to use an inkjet printer for the imagewise application of the masking fluid.

In this specification, the phrase “the mask being in the form of the image to be printed” is used to describe a situation where the mask is specifically the positive image of the image to be printed. The mask only needs to resist the developer to such a degree that, during the period required to remove positive-working radiation-imageable medium that is exposed to the developer, the positive-working radiation-imageable medium coated with the mask is not significantly removed.

In this specification, the term “negative-working radiation-imageable medium” is used to describe a medium which, when coated as a layer on a lithographic base, will be hydrophilic and will become hydrophobic, or be removable by a developer to reveal an underlying hydrophilic surface, when irradiated with that particular radiation. Conversely, the term “positive-working radiation-imageable medium” is used to describe a medium which, when coated as a layer on a lithographic base, will be hydrophobic and will either become hydrophilic, or be removable by a developer to reveal an underlying hydrophilic surface, when irradiated with that particular radiation. It will be understood that, in a preferred method of the present invention, the positive-working radiation-imageable medium is not irradiated with radiation to produce an image; rather, the positive-working radiation-imageable medium (more precisely, the unmasked part of it) is removed by a developer to produce the desired image.

In this specification, the term “negative-working lithographic master” is used to describe a lithographic master on which, during the process of transferring printing ink from the master to a printing medium for receiving printing ink, the printing ink adheres to those areas that were irradiated or written to in any way whatsoever by an imaging head and, conversely, on which printing ink does not adhere to those areas that were not irradiated or written to in any way by that imaging head. Whether the master is referred to as negative-working or positive-working is therefore not determined by the means of creating ink-bearing and non-ink-bearing areas on the master, but rather on whether the positive image to be created on the printing medium for receiving the printing ink, or the negative of it, is transferred to the master from the imaging head. In brief, on a “negative-working lithographic master”, those areas that are written by the imaging head will carry printing ink.

In accordance with the preferred embodiment of the invention, a computer-to-plate system comprising an inkjet printer and a conventional developing processor machine is used. In the most preferred embodiment, the inkjet printer used is a commercially-available drop-on-demand printer capable of printing small ink drops, such as, for example, the EPSON Stylus Color 3000 inkjet printer available from Epson America, Inc., Long Beach, Calif. In an alternative embodiment a continuous inkjet printer head can be used such as those supplied by Iris Graphics of Billerica, Mass. However, the great flexibility available to the practitioner in formulating a masking fluid according to the invention means that a well-performing jettable masking fluid can be formulated such that the printhead of almost any inkjet printer will be able to form regular drops with good reliability.

The imagewise-deposited masking fluid applied to the positive-working offset lithographic precursor imagewise coats the layer of positive-working radiation-imageable medium. In the affected areas of the coating, a layer is created which is substantially impermeable to the developer. The mask is preferably non-transmissive to UV radiation. The printed areas may exhibit a slight color change, which may be the result of an indicator dye added to the masking solution for the purpose of enabling inspection of the imaged plate or before development. When the precursor is processed or washed with the developer, the unprinted areas of the coating are quantitatively removed, leaving bare the hydrophilic aluminum base of the positive-working plate, while the previously masked areas of the coating are hydrophobic and can carry printing ink. The lithographic master so produced is therefore a negative-working lithographic master, suitable for wet lithographic offset printing.

The masking fluid comprises a liquid vehicle, typically water or a mixture of water and another solvent or alternatively solvents such as methyl ethyl ketone, ethyl acetate, dimethyl formamide, acetone, simple alcohols, and other like chemicals, or mixtures of such chemicals, provided the solvent or mixture of solvents does not substantially remove the imageable coating of the lithographic plate. The vehicle also contains an active masking ingredient.

A class of compounds useful in a masking fluid are nitrogen-containing compounds wherein at least one nitrogen atom is either quarternised, or incorporated in a heterocyclic ring, or both quarternised and incorporated in a heterocyclic ring.

Examples of useful quarternised nitrogen-containing compounds are triaryl methane dyes such as Crystal Violet (Cl basic violet 3) and Ethyl Violet, Basic Blue 7 and tetraalkyl ammonium compounds such as Cetrimide and benzotrimethyl ammonium salts. Examples of suitable nitrogen-containing heterocyclic compounds are quinoline and triazoles, such as 1,2,4-triazole, imidazoles, and indoles. Examples of suitable quarternised heterocyclic compounds are imidazoline compounds, such as Monazoline C, Monazoline O and Monazoline T, which are manufactured by Mona Industries, quinolinium compounds, such as 1-ethyl-2-methyl quinolinium iodide and 1-ethyl-4-methyl quinolinium iodide, and benzothiazolium compounds, such as 3-ethyl-2-methyl benzothiazolium iodide, and pyridinium compounds, such as cetyl pyridinium bromide, ethyl viologen dibromide and fluoropyridinium tetrafluoroborate. Usefully, the quinolinium or benzothiazolium compounds are cationic cyanine dyes, such as Dye A, Quinoldine Blue and 3-ethyl-2-[3-(3-ethyl-2(3H)-benzothiazoylidene)-2-methyl-1-propenyl]benzothiazolium iodide.

A further useful class of compounds suitable for use in a masking fluid are carbonyl functional group-containing compounds. Examples of suitable carbonyl-containing compounds are flavones, such as 7,8-benzoflavone, trihydroxyflavone, and naphthaflavone; flavanones or isoflavanones, for example hydroxy-dimethoxyflavanone; coumarins; chromones; indeneones; chalcones; xanthones; thioxanthones; benzophenones; phthalimides; and phenanthrenequinones.

Other suitable classes of materials are polysubstituted siloxanes such as polyphenylsiloxane, substituted pyrans and the like and perfluorinated compounds.

Another useful compound for use in a masking fluid is acridine orange base (Cl solvent orange 15).

A preferred ink comprises a vehicle with 0.5 to 5.0 weight percent of active masking ingredient.

Various additions may be made to the masking fluid employed in the present invention in order to improve its functioning. For reliable jetting, and so that during idle periods the masking fluid does not dry out in the inkjet nozzle causing it to clog, a humidifying co-solvent may be added to the masking fluid. The co-solvent can be polyhydric alcohols such as glycerin, ethoxylated glycerin, ethylene glycol, diethylene glycol, triethylene glycol, propylene glycol, dipropylene glycol, or trimethylol propane, other high boiling point liquids such as pyrrolidone, methylpyrrolidone, or triethanol amine, other simple alcohols such as isopropyl alcohol or tertiary butyl alcohol, or mixtures of such solvents. When used, the co-solvent would typically comprise 1 to 40 percent weight of the masking fluid.

A dye compatible with the vehicle may also be added at a level of a few percent to enhance the visibility of the latent image. This is useful in facilitating the inspection of the imaged plate, before it is subjected to the developer.

The masking fluid may also optionally contain one or more surfactants or wetting agents to control the surface tension of the masking fluid, enhancing jettability, and to control the spread of the drop on the coated plate. The surfactants and wetting agents may include Iconol DA, Iconol NP, Iconol OP, Iconol TDA, Surfonyl TDA, Surfonyl TG-E, Strodex, Cal-Fax, Tergitol TMN, Tergitol X, Tergitol 15-S, IPA, Iso-butanol, and similar chemicals or mixtures of similar chemicals. When used, surfactants and wetting agents typically comprise 0.001 to 10 percent of the masking fluid.

The masking fluid may additionally contain biocides to prolong the shelf life of the ink. Suitable biocides include for Kathon PFM, CanGuard 409, Sumquat 6020, and similar chemicals or mixtures of such chemicals. When used, the biocide would typically comprise 0.1 to 3 percent of the masking fluid.

A preferred formulation for a masking fluid comprises: Water 67%: Co-solvent 25%: mask 3%: dye 2%: surfactant 2% : Biocide 1%

Regarding the lithographic plates employed in the present invention, and, more particularly, the coatings of positive-working radiation-imageable medium on them, 1,2-naphthoquinone-2-diazide4- or -5-sulfonyl derivatives are preferably used as the quinonediazide. The esters are particularly preferred. Suitable naphthoquinonediazides are known from U.S. Pat. Nos. 3,106,465, 3,180,733 and 4,266,001. The quantity of the naphthoquinonediazide compounds in the positive-working radiation-imageable medium is generally between about 3 and 50, and preferably between about 8 and 25, percent by weight, relative to the content of the nonvolatile constituents.

The novolak polycondensates, proven in many positive copying materials based on 1,2-quinonediazides, have here again proved to be advantageous as binders in the positive-working radiation-imageable media compositions. The novolaks additionally can have been modified in a known manner by reaction of a part of their hydroxyl groups with, for example, chloroacetic acid, isocyanates, epoxides or carboxylic acid anhydrides. Further alkali-soluble or alkali-swellable binders are polyhydroxyphenyl resins that are prepared by condensation from phenols and aldehydes or ketones, or polymers or copolymers of styrene and maleic anhydride, or polyvinylphenols. Advantageously, a polymer or copolymer of an acrylic or methacrylic acid ester with a polyhydric phenol can be used. The nature and quantity of the alkali-soluble resin can differ depending on the intended use; preferably, proportions of between about 90 and 30, and especially between about 85 and 55, percent by weight of total solids are preferred. Additionally, polymers made from the reaction between polyvinyl alcohol and hydroxyphenyl-substituted aldehydes and other aldehydes such as butyraldehyde can be used.

The binders used are preferably those that have a content of phenolic hydroxyl groups in the range from about 1 to 15 mmol/g and a molecular weight below about 100,000, especially in the range from about 5,000 to 100,000.

Numerous other resins can also be used in combination. The combination of a cresol/formaldehyde novolak and an unplasticized, preferably alkyl-etherified melamine/formaldehyde resin has proved to be particularly advantageous. In addition, epoxy resins and vinyl copolymers of the monomers on which they are based, and hydrogenated or partially hydrogenated colophony derivatives can also be present as resins. The advantageous proportion of these resins depends on the application requirements and on the effect on the development conditions. The proportion is generally not more than about 40, and preferably about 1 to 20, percent by weight, relative to alkali-soluble binder. For special requirements, such as flexibility, adhesion, gloss and coloration, the layer of positive-working radiation-imageable medium can also contain small quantities of substances such as polyglycols, cellulose derivatives such as ethylcellulose, wetting agents, dyes, adhesion promoters and finely disperse pigments and also, if required, UV-absorbers.

Small amounts of materials may be included for the color change during exposure to UV radiation when the plates are used in their normal roles as ultraviolet-sensitive plates. These materials are present but typically are unaffected by the materials used to produce the plates made by the process of the present invention. Examples of these materials are cationic triarylmethane dyes and methine dyes. The radiation-sensitive components are, for example, 1,2-naphthoquinonediazide-4-sulfonic acid chloride, chromophorically-substituted halogenomethyl-s-triazines or diazonium compounds in the form of their salts with complex acids such as tetrafluoboric acid or hexafluorophosphoric acid.

For coating a suitable lithographic base, i.e., for producing the positive-working radiation-imageable medium in a form to be coated, the mixture is generally dissolved in a solvent. The choice of solvent must be matched to the intended coating method, to the layer thickness and to the drying conditions. Suitable solvents are ketones such as methyl ethyl ketone, chlorinated hydrocarbons such as trichloroethylene and 1,1,1-trichloroethane, alcohols such as n-propanol, ethers such as tetrahydrofuran, alcohol ethers such as ethylene glycol monoalkyl ethers and propylene glycol monoalkyl ethers, and esters such as butyl acetate or propylene glycol alkyl ether-acetate. Mixtures can also be used that additionally, for special purposes, contain solvents such as acetonitrile, dioxane or dimethylformamide. In principle, all solvents can be used that do not react irreversibly with the layer components. Partial ethers of glycols, especially ethylene glycol monomethyl ether and propylene glycol methyl ether, are particularly preferred.

The lithographic bases used in most cases are metals. The following are used preferably for offset printing plates: bright-rolled, mechanically or electrochemically roughened aluminum which may have been anodized and which additionally can have been pretreated chemically, for example, with polyvinylphosphonic acid, silicates, phosphates, hexafluorozirconates or with hydrolyzed tetraethyl orthosilicate.

The coating of the layer support is effected in a known manner by spraying, dipping, roller application, by means of slot dies, blade-application or coater-application.

The developer used is one capable of removing the unmasked areas of the medium without the need for any irradiation of the medium, while not removing the masking. A preferred class of compositions having such capability is quaternary nitrogen compounds in a carrier such as water. A preferred such composition is tetramethylammonium hydroxide in water. The composition is preferably 5-25% tetramethylammonium hydroxide and more preferably 10-20%, by volume.

The invention also relates to a process for producing a lithographic master by exposing the positive-working radiation-imageable medium to the mask fluid, then developing with an aqueous-alkaline solution, and gumming, which process comprises using a recording material according to the invention.

After application of the masking fluid, the plate may be optionally heated. Such optional heating may be to temperatures between 40 and 130 C. for between 10 seconds and 3 minutes, for the purposes of curing the masking fluid to create the mask. After the application of the masking fluid and optional heating, the plate is developed either by hand or preferably with a conventional developing processor using a conventional developing solution. The plate is then gummed in accordance with processes well known to those skilled in the art of offset platemaking to produce a plate ready for printing. If desired, because of the printing application, the developed plate may be post-baked, or gummed and post-baked to achieve an additional toughening of the plate coating. These treatments are well known to practitioners of the art. An example treatment is described in patent GB1,513,368.

Plates coated with solvent-borne photosensitive polymer solutions not containing photosensitizing quinonediazide resins can also be prepared according to the invention if the jetted masking fluid forms a well-defined dot on the coating without spreading excessively and a differential in solubility in the developer is obtained.

To facilitate accurate imaging of the precursor, the paper-handling or substrate-handling subsystem of the inkjet printer should have a short, straight paper path. A printing precursor is generally stiffer and heavier than the paper or media typically used in commercially-available inkjet printers. If the precursor fed into the printer mechanism must bend before or after being presented to the imaging printhead, the movement of the precursor through the printer may not be as accurate as the media for which the printer was designed. The most preferred EPSON Stylus Color 3000 has such a short, straight paper path. A platen is preferably placed at the entrance to the paper feed mechanism. The platen supports the presursor as it is pulled into the printer by the mechanism, facilitating the accurate transport of the plate under the imaging printhead.

The combination comprising the positive-working radiation-imageable medium and masking fluid may optionally be used in an apparatus that combines the making of the a positive-working offset lithographic precursor and the imagewise deposition of the masking fluid. As described in U.S. Pat. No. 5,713,287 (Gelbart), a cylindrical hydrophilic lithographic base may be coated with a positive-working offset radiation-imageable medium and the coated layer may be cured to create the positive-working offset lithographic precursor. The inkjet deposition of the masking fluid may then be performed. The hydrophilic lithographic base may be a plate or a sleeve that fits on or over a cylinder or drum. The plate and sleeve may be re-usable. Instead of using a separate plate or sleeve as hydrophilic lithographic base, a suitably hydrophilic drum or cylinder may be employed. The entire plate-making arrangement may be incorporated on a press to create a fully on-press plate-making facility. The hydrophilic lithographic base may also be re-usable upon removal of any existing imaged areas of positive-working offset radiation-imageable medium, this being particularly useful in the case where the drum or cylinder itself provides the hydrophilic lithographic base.

In an alternative embodiment, rather than removing the unmasked areas of the radiation-imageable medium from the lithographic base by means of a developer capable of doing so without irradiation of the medium, the radiation-imageable medium is, after the masking step, flood illuminated with radiation of a suitable wavelength, for example ultraviolet, and the unmasked areas are then removed using a conventional developer of the type capable of removing the irradiated medium. Such developers are well known in the art and are generally aqueous alkaline solutions of graded alkalinity, preferably having a pH in the range of 10-14, which can also contain small quantities of organic solvents, surfactants and sequestering agents. Any of various commercially-available developers used for the development of positive-working radiation-imageable media can be used, including GOLDSTAR PLUS PD (trademark) manufactured by Eastman Kodak Company of Rochester, N.Y., EP26 (trademark) manufactured by Agfa-Gavaert of Mortsel, Belgium, and DP4 and DP5 (trademarks) manufactured by Fuji Hunt Photographic Chemicals, Inc. of Allendale, N.J.

There have thus been outlined the important features of the invention in order that it may be better understood, and in order that the present contribution to the art may be better appreciated. Those skilled in the art will appreciate that the conception on which this disclosure is based may readily be utilized as a basis for the design of other methods and apparatus for carrying out the several purposes of the invention. It is most important, therefore, that this disclosure be regarded as including such equivalent methods and apparatus as do not depart from the spirit and scope of the invention.

What is claimed is:

1. A method for making a negative-working lithographic master for wet offset lithographic printing of an image on a printing medium, comprising the steps of:
(a) coating a layer of positive-working radiation-imageable medium onto a hydrophilic lithographic base;
(b) forming a mask on the surface of said radiation-imageable medium, said mask being in the form of said image and substantially resistant to a developer; and
(c) exposing said layer of radiation-imageable medium to said developer to remove the areas of said radiation-imageable medium that are not covered by said mask.

2. A method for making a negative-working lithographic master, said method comprising the step of imaging a positive-working radiation-imageable medium on a hydrophilic lithographic base.

3. A method for making a negative-working lithographic master for wet offset lithographic printing of an image on a printing medium, comprising the steps of:
(a) providing a lithographic precursor comprising a layer of positive-working radiation-imageable medium coated on a hydrophilic lithographic base;
(b) forming a mask on the surface of said radiation-imageable medium, said mask being in the form of said image and substantially resistant to a developer; and
(c) exposing said layer of radiation-imageable medium to said developer to remove the areas of said medium that are not covered by said mask.

4. A method for making a negative-working lithographic master from a positive-working radiation-imageable medium, comprising the step of imagewise depositing droplets of a masking fluid onto a layer of positive-working radiation-imageable medium on a hydrophilic lithographic base.

5. A method of performing wet offset printing of an image on a printing medium, comprising the steps of:
(a) providing an offset lithographic precursor comprising a layer of positive-working radiation-imageable medium on a hydrophilic lithographic base;
(b) forming a mask upon the surface of said radiation-imageable medium, said mask being in the form of said image and substantially resistant to a developer;
(c) forming a lithographic master by exposing said layer of radiation-imageable medium to said developer to remove the areas of said developer that are not covered by said mask; and
(d) performing wet offset lithographic printing with said lithographic master.

6. A method for wet offset printing, said method comprising the steps of:
(a) making a negative-working lithographic master from a positive-working radiation-imageable medium; and
(b) performing wet offset lithographic printing with said lithographic master.

7. A negative-working lithographic master produced in accordance with the method of claim 1.

8. A lithographic master in accordance with claim 6 wherein said base is one of:
(a) a disposable plate;
(b) a re-usuable plate;
(c) a printing cylinder of a printing press; and
(d) a seamless sleeve for a printing cylinder of a printing press.

9. A negative-working wet lithographic master comprising areas of hydrophobic positive-working radiation-imageable medium on a hydrophilic lithographic base.

10. A masked lithographic printing precursor for use in the wet offset printing of an image, comprising:
(a) a hydrophilic lithographic base;
(b) a layer of positive-working radiation-imageable medium coated on said base; and
(c) a mask formed upon the surface of said layer of radiation-imageable medium, said mask being in the form of said image and substantially resistant to a developer.

11. A method according to claim 1 wherein said step of forming a mask comprises depositing droplets of a masking fluid.

12. A method according to claim 11 wherein said depositing is done by means of an inkjet printer.

13. A method according to claim 1 wherein said step of forming a mask includes the steps of curing said mask.

14. A method according to claim 13 wherein said curing is done by heating.

15. A method according to claim 14 wherein said heating is done at a temperature in the range of 40-130° C. for a time in the range of 10 seconds to 3 minutes.

16. A method according to claim 1 further comprising the step of hardening the part of said layer of medium that remains on said base.

17. A method according to claim 1 further comprising, after step (c), the step of removing said mask.

18. A method according to claim 11 wherein said masking fluid comprises an indicator dye.

19. A method according to claim 11 wherein said masking fluid comprises an active masking ingredient and a solvent.

20. A method according to claim 19 wherein said solvent comprises water.

21. A method according to claim 19 wherein said solvent comprises an organic solvent.

22. A method according to claim 19 wherein said solvent comprises water and an organic solvent.

23. A method according to claim 9 wherein said masking fluid comprises a nitrogen-containing compound wherein at least one nitrogen atom is:
(a) quarternized; or
(b) incorporated in a heterocyclic ring; or
(c) both quarternized and incorporated in a heterocyclic ring.

24. A method according to claim 23 wherein said nitrogen-containing compound is one of sub-paragraph:
(a) a triaryl methane dye, and
(b) a tetraalkyl ammonium compound.

25. A method according to claim 23 wherein said nitrogen-containing compound is one of:
(a) a quinoline;
(b) a triazole;
(c) an imidazole; and
(d) an indole.

26. A method according to claim 25 wherein said nitrogen-containing compound is 1,2,4-triazole.

27. A method according to claim 24 wherein said nitrogen-containing compound is one of:
(a) Crystal Violet;
(b) Ethel Violet; and
(c) Basic Blue 7.

28. A method according to claim 24 wherein said nitrogen-containing compound is one of:
(a) cetrimide; and
(b) a benzotrimethyl ammonium salt.

29. A method according to claim 23 wherein said nitrogen-containing compound is a quinolinium compound.

30. A method according to claim 29 wherein said quinolinium compound is one of:
(a) 1-ethyl-2-methyl quinolinium iodide; and
(b) 1-ethyl-4-methyl quinolinium iodide.

31. A method according to claim 23 wherein said nitrogen-containing compound is a benzothiazolylidene compound.

32. A method according to claim 31 wherein said benzothiazolyidene compound is 3-ethyl-2-methyl benzothiazolium iodide.

33. A method according to claim 23 wherein said nitrogen-containing compound is a pyridinium compound.

34. A method according to claim 33 wherein said pyridinium compound is one of:
(a) cetyl pyridinium bromide;
(b) ethyl viologen dibromide; and
(c) fluoropyridinium tetrafluoroborate.

35. A method according to claim 29 wherein said quinolinium compound is a cationic cyanine dye.

36. A method according to claim 35 wherein said dye is one of:
(a) Dye A; and
(b) Quinoldine Blue.

37. A method according to claim 31 wherein said benzothiazolium compound is 3-ethyl-2-[3-ethyl-2(3H)-benzothiazoylidene)-2-methyl-1-propenyl] benzothiazolium iodide.

38. A method according to claim 11 wherein said masking fluid comprises one of:
(a) a flavone;
(b) a flavonone;
(c) an isoflavanone;
(d) a coumarin;
(e) a chromone;
(f) an indeneone;
(g) a chalcone;
(h) a xanthone;
(i) a thioxanthone;
(j) benzophenone;
(k) a phthalimide; and
(l) a phenanthrenequinone.

39. A method according to claim 38 wherein said flavone is one of:
(a) 7,8-benzoflavone;
(b) trihydroxyflavone; and
(c) naphthaflavone.

40. A method according to claim 38 wherein said flavanone is hydroxy-dimethoxyflavanone.

41. A method according to claim 11 wherein said masking fluid comprises a poly substituted siloxane.

42. A method according to claim 41 wherein said siloxane is polyphenylsiloxane.

43. A method according to claim 11 wherein said masking fluid comprises a substituted pyran.

44. A method according to claim 11 wherein said making fluid comprises a perfluorinated compound.

45. A method according to claim 11 wherein said masking fluid comprises acridine orange base.

46. A method according to claim 19 wherein the amount of said active masking ingredient is in the range of 0.5-5 weight % of said masking fluid.

47. A method according to claim 11 wherein said masking fluid further comprises one or more of:
(a) a humidifying co-solvent;
(b) a dye;
(c) a surfactant or wetting agent; and
(d) a biocide.

48. A method according to claim 1 wherein said radiation-imageable medium is a quinonediazide.

49. A method according to claim 48 wherein said quinonediazide is a 1,2-naphthoquinone-2-diazide-4- or -5-sulfonyl derivative.

50. A method according to claim 48 wherein said quinonediazide is a naphthoquinonediazide.

51. A method according to claim 50 wherein the amount of said naphthoquinonediazide is in the range of 3-50 weight % relative to the weight of non-volatile components of said radiation-imageable medium.

52. A method according to claim 1 wherein said radiation-imageable medium comprises a binder.

53. A method according to claim 52 wherein said binder is a novolak polycondensate.

54. A method according to claim 52 wherein said binder is a polyhydroxyphenyl resin.

55. A method according to claim 52 wherein said binder is a polymer or co-polymer of an acrylic or methacrylic acid ester with a polyhydricphenol.

56. A method according to claim 52 wherein the amount of said binder is in the range of 30-90% by weight relative to total solids in said medium.

57. A method according to claim 52 wherein the amount of said binder is in the range of 50-85% by weight relative to total solids in said medium.

58. A method according to claim 52 wherein said binder has pheonolic hydroxyl groups present in the range of about 1-15 mmol/g and a molecular weight up to 100,000.

59. A method according to claim 52 wherein said binder comprises a combination of a cresol/formaldehyde novolak and an unplasticized, alkyl-etherified melamine/formaldehyde resin.

60. A method according to claim 1 wherein said radiation-imageable medium comprises or more of:
(a) a polyglycol;
(b) a cellulose derivative;
(c) a dye;
(d) an adhesion promoter;
(e) a pigment; and
(f) a UV-absorber.

61. A method according to claim 1 wherein said step of coating comprises dissolving said radiation-imageable medium in a solvent and applying it by one of:
(a) spraying;
(b) dipping;
(c) roller application;
(d) slot dies;
(e) blade application; and
(f) coater application.

62. A method according to claim 1 wherein said lithographic base is anodized aluminum.

63. A method according to claim 1 wherein said developer is an aqueous alkaline solution.

64. A method according to claim 63 wherein said solution has a pH in the range of 10-14.

65. A method according to claim 63 wherein said solution further includes one or more of:
(a) an organic solvent;
(b) a surfactant; and
(c) a sequestering agent.

66. A method according to claim 1, further including the step, after step (b), of flood-illuminating said layer of radiation-imageable medium with ultra-violet radiation, and wherein said developer is a developer of the type capable of removing the areas of said radiation-imageable medium that are not covered by said mask after said radiation-imageable medium has been illuminated with ultra-violet radiation.

67. A method according to claim 66 wherein said developer comprises a quaternary nitrogen compound.

68. A method according to claim 67 wherein said developer comprises tetramethylammonium hydroxide in water.

69. A masking fluid for forming a mask on the surface of a layer of positive-working radiation-imageable medium, comprising:
(a) an active masking ingredient that is substantially resistant to a developer; and
(b) a solvent capable of dissolving said active masking ingredient and of not substantially removing said positive-working radiation-imageable medium from a hydrophilic lithographic base.
